(19) United States
(12) Patent Application Publication
(10) Pub. No.: US 2015/0342081 A1
(43) Pub. Date: Nov. 26, 2015

(54) CASE CABLE ORGANIZER STRUCTURE

(71) Applicant: NAN JUEN INTERNATIONAL CO., LTD., NEW TAIPEI CITY (TW)

(72) Inventor: FU-TIEN CHANG, NEW TAIPEI CITY (TW)

(21) Appl. No.: 14/285,313

(22) Filed: May 22, 2014

(51) Int. Cl. H05K 7/18

(52) U.S. Cl. CPC H05K 7/18

(57) ABSTRACT

A case cable organizer structure, comprising: a front cable tray unit comprising a first front cable tray and a second front cable tray which is pivoted on and stays behind the first front cable tray and has board's pin-jointed ends at one side; a central shifting board which is arranged behind the second front cable tray and provided with pin-jointed parts securely fixed at central front and rear sides wherein the pin-jointed part at the front side is pivoted on board's pin-jointed ends of the second front cable tray; a rear cable tray unit comprising a first rear cable tray and a second rear cable tray which is pivoted on the first rear cable and is arranged in the front of the first rear cable tray and has board's pin-jointed ends at one side wherein the board's pin-jointed ends are pivoted on a pin-jointed part at the rear end of the central shifting board.

### BACKGROUND OF THE INVENTION

1. Field of the Invention

The present disclosure relates to a case cable organizer, particularly a case cable organizer structure which is easily manufactured and features simplified components for stabilized operation.

2. Description of the Related Art

The existing mainframe computer/electronic equipment system is usually held and stacked in a cabinet which is internally provided with slide tracks at both sides for easily assembling or maintaining computers/electronic devices (e.g., servers). In this context, the complex cables connected to back sides of computers/electronic devices should be accommodated and held in cable organizers for no cable getting tangled or falling off in the course of moving cases of computers/electronic devices. As disclosed in U.S. Pat. No. 1,336,229, a conventional cable organizer comprises a cable tray body, a support frame, a support slipper, a support fastener, and two mounting elements: the cable tray body comprises a front-arm cable tray, a rear-arm cable tray, a central cable tray and a slide bushing which is connected to the central cable tray and held in the support frame; the support frame allows both ends to link the support slipper and the support fastener, respectively; the two mounting elements link the cable tray body's both ends. The central cable tray pivoted on the slide bushing is provided with curved slots opposite to stoppers on the slide bushing which makes turning relative to the central cable tray in a specific range; the front-arm cable tray of the cable tray body relies on mounting pieces to be held in a socket at an internal track's rear end; the rear-arm cable tray of the cable tray body relies on mounting pieces to be held in a socket at an external track's rear end; the support frame has one end at which the support slipper connected to an inner rod is movably shifted in the external tack and the other end at which the support fastener connected to an outer rod is held in a stator at the rear end of a central track so that the cable tray body follows outstretched slipping components for extension and slip on the support frame.

The conventional cable organizer which satisfies supporting and operating functions still has some drawbacks, for example, the cable organizer with a linear main body laterally stretching and a support frame deflecting for movement performs an asymmetric deflective motion, which makes the support frame jammed or seized or friction-induced noise in the course of an asymmetric drag, and is not a good design. Furthermore, the conventional cable organizer features a design of an asymmetric deflection complicating components therein and comprises the components that have nothing in common but increase manufacturing and assembling costs without economic effect, all of which deserve to be further improved. Therefore, how to solve these problems is an important issue confronted by the persons skilled in the art.

Accordingly, the applicant/inventor considered imperfect structural design and drawbacks of the conventional cable organizer and attempted to optimize a solution, that is, a case cable organizer structure with simplicity, operational stability and economic effect for promoting development of the industry.

### SUMMARY OF THE INVENTION

The present disclosure is to provide a case cable organizer structure featuring simplicity, steady and smooth running, and economic effect as well as operation quality in manufacture and utility.

For the above purposes, the case cable organizer comprises technical measures as follows: a front cable tray unit comprising a first front cable tray and a second front cable tray which is pivoted on and stays behind the first front cable tray and has board's pin-jointed ends at one side; a central shifting board which is arranged behind the second front cable tray and provided with pin-jointed parts securely fixed at central part of central shifting board's front and rear sides wherein the pin-jointed part at the front side is pivoted on board's pin jointed ends of the second front cable tray; a rear cable tray unit comprising a first rear cable tray and a second rear cable tray, the second rear cable tray is pivoted on the front of the first rear cable tray and has board's pin-jointed ends at one side wherein the board's pin-jointed ends are pivoted on a pin-jointed part at the rear end of the central shifting board.

In the above case cable organizer, both the first front cable tray and the second front cable tray are tubular frames in which wiring spaces are designed and the first front cable tray has track's pin-jointed ends at one side.

In the above case cable organizer, the track's pin-jointed ends are pivoted on an inner-track pin joint from which a locator with some pilot holes thereon protrude outward.

In the above case cable organizer, the second front cable tray is pivoted on the first front cable tray by a movable part which has pin-jointed ends at both ends pivoted on the first front cable tray and the second front cable tray, respectively.

In the above case cable organizer, the central shifting board has a guiding groove with two fixing pieces embedded at both ends and the fixing piece comprises a straight-down solid joint piece on which fixing holes are drilled.

In the above case cable organizer, the central part of the central shifting board is provided with a shifting pin-jointed member to which front and rear pin-jointed parts are connected.

In the above case cable organizer, both the first rear cable tray and the second rear cable tray are tubular frames in which wiring spaces are designed and the first rear cable tray has device's pin jointed ends at one side.

In the above case cable organizer, the device's pin-jointed ends are pivoted on a cabinet pin joint comprising a pin-jointed plate and a fixed plate, both of which are perpendicularly connected to each other.

In the above case cable organizer, the second rear cable tray is pivoted on the first rear cable tray by a movable part which has pin-jointed ends at both ends pivoted on the first rear cable tray and the second rear cable tray, respectively.

In the above case cable organizer, the cabinet pin joint and an external track are both securely fixed on a cabinet, a central tack movably held in the external track and an internal track movably held in the central tack, a case of a computer/electronic device installed in the cabinet is connected to the internal track, the fixing piece is securely fixed on the central tack, and the inner-track pin joint is firmly fixed on the inner track.

### BRIEF DESCRIPTION OF THE DRAWINGS

FIG. 1 is a schematic view of an assembled case cable organizer.

FIG. 2 is an exploded view of a case cable organizer.

FIG. 3 is a schematic view illustrating an application of an assembled case cable organizer.

FIG. 4 is a schematic view 1 illustrating a case cable organizer in operation.

FIG. 5 is a schematic view 2 illustrating a case cable organizer in operation.

### DETAILED DESCRIPTION OF THE PREFERRED EMBODIMENTS

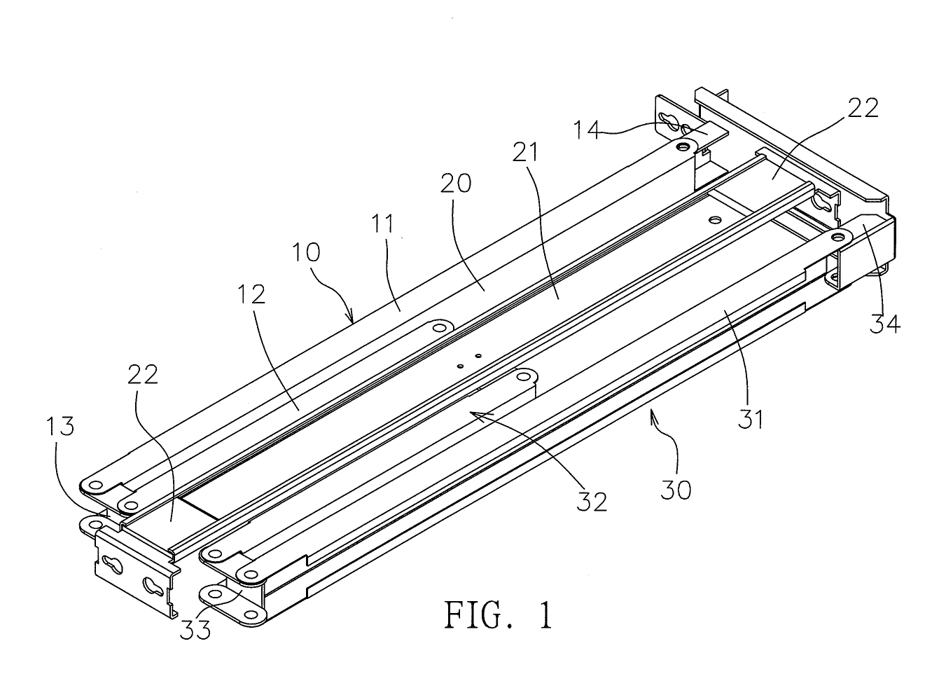

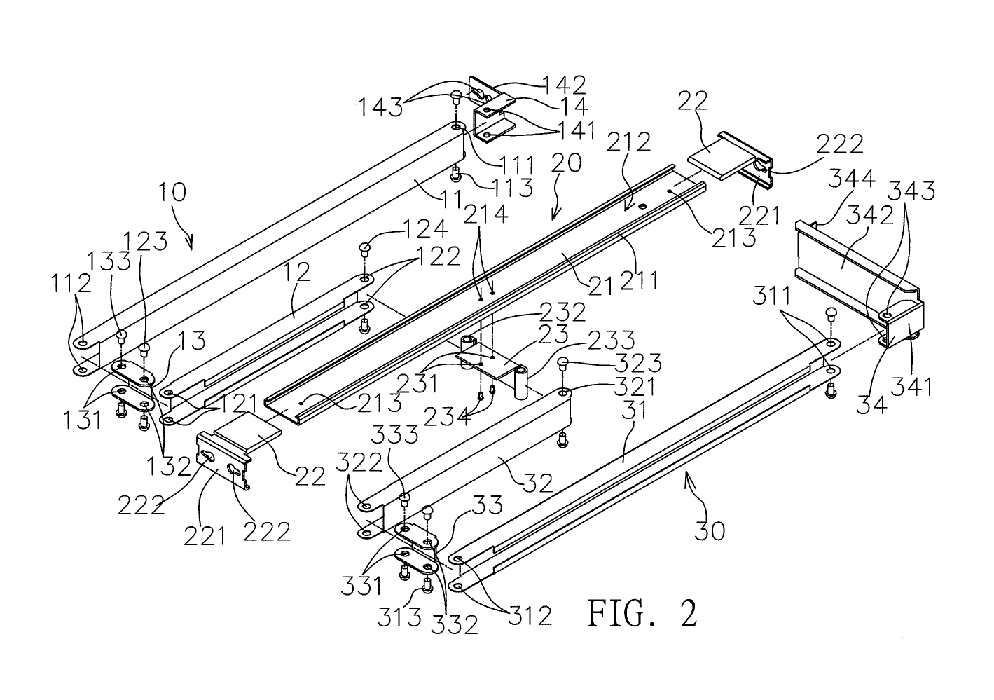

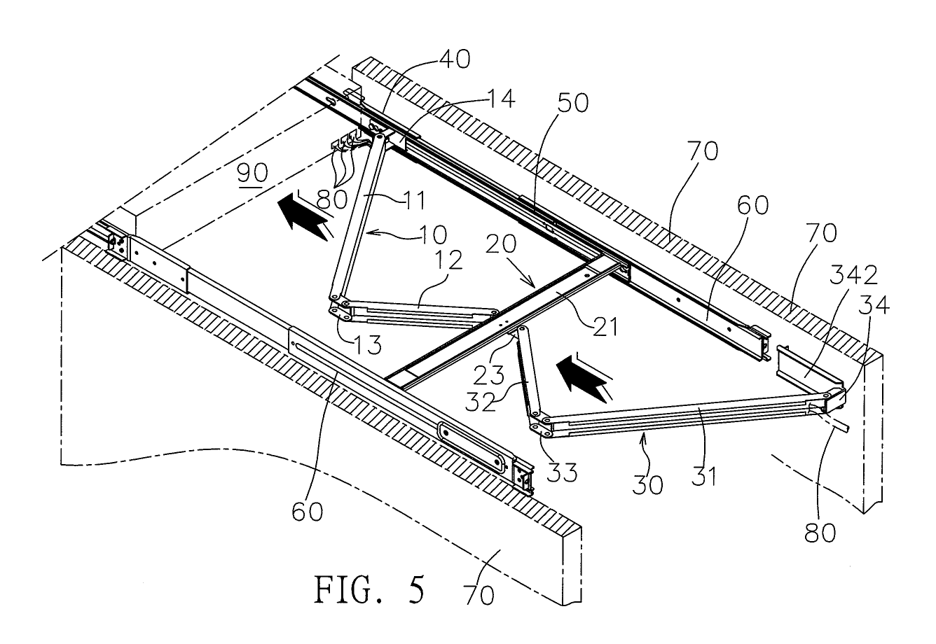

Please refer to FIGS. 1 and 2 which illustrate a case cable organizer in the present disclosure comprises a front cable tray unit 10, a shifting device 20 and a rear cable tray unit 30. The front cable tray unit 10 comprises a first front cable tray 11 and a second front cable tray 12, both of which are pivoted on each other. The first front cable tray 11 and the second front cable tray 12 are U-shaped tubular frames in which wiring spaces are designed for accommodation of a cable 80 (FIG. 5). The first front cable tray 11 has track's pin-jointed ends 111 at one side and tray's pin-jointed ends 112 at the other end wherein the track's pin jointed ends 111 are pivoted on an inner-track pin joint 14, which has two pin-jointed ends 141 positioned to the track's pin-jointed ends 111 by rivet pins 113, for pivoted on the first front cable tray 11 and the inner-track pin joint 14. The inner-track pin joint 14 develops a forward protruding locator 142 on which pilot holes 143 are drilled. The second front cable tray 12, which is arranged behind the first front cable tray 11 and less than the first front cable tray 11 in length, comprises tray's pin-jointed ends 121 at one side as well as board's pin-jointed ends 122 at the other end and depends on the tray's pin-jointed ends 121 to pivot on the first front cable tray 11. In a preferable embodiment, the second front cable tray 12 is pivoted on the first front cable tray 11 by a movable part 13 which has two pin-jointed ends 131, 132 pivoted on the tray's pin-jointed ends 112, 121 by two rivet pins 133, 123.

The shifting device 20 which is pivoted between the front cable tray unit 10 and the rear cable tray unit 30 comprises a central shifting board 21, two fixing pieces 22 at both ends and a shifting pin-jointed member 23: the central shifting board 21 has two raised borders 211 at front and rear sides for development of a guiding groove 212 as an embedding space, mounting holes 214 centrally, and pilot holes 213 (positioning bumps) at both ends; the fixing piece 22, which is embedded into one side of the guiding groove 212 on the central shifting board 21, develops not only positioning bumps (or pilot holes not shown in figures) corresponding to the pilot holes 213 (positioning bumps) but also a straight-down solid joint piece 221 on which fixing holes 222 are drilled; the shifting pin-jointed member 23 develops not only mounting holes 231 through which locking members 234 (e.g., bolts, etc.) are fixed in the mounting holes 214, 231 and the shifting pin-jointed member 23 is securely connected to the center of the central shifting board 21 but also two securely connected pin-jointed parts 232, 233 located at front and rear ends and facing the front cable tray unit 10 and the rear cable tray unit 30 wherein the pin-jointed part 232 is pivoted on the board's pin-jointed end 122 on the second front cable tray 12 by rivet pins 124, allowing the central shifting board 21 to be driven by the second front cable tray 12 simultaneously. In a proper embodiment, both the central shifting board 21 and the shifting pin-jointed member 23 is formed integrally, that is, the central shifting board 21 is directly provided with the pin-jointed parts 232, 233 at central front and rear sides.

The rear cable tray unit 30 comprises a first rear cable tray 31 and a second rear cable tray 32, both of which are pivoted on each other. The first rear cable tray 31 and the second rear cable tray 32 are U-shaped tubular frames in which wiring spaces are designed for accommodation of a cable 80 (FIG. 5). The rear cable tray 31 has device's pin-jointed ends 311 at one side and tray's pin jointed ends 312 at the other end wherein the device's pin-jointed ends 311 are pivoted on a cabinet pin joint 34 comprising a pin-jointed plate 341 and a fixed plate 342, both of which are connected and perpendicular to each other: the pin-jointed plate 341 has pin-jointed ends 343 positioned to the device's pin-jointed ends 311 by rivet pins for pivoted on the first rear cable tray 31 and the cabinet pin joint 34; the fixed plate 342 and the pin-jointed plate 341 are provided with a tag 344 at the side opposite to their junction. The second rear cable tray 32, which is arranged in the front of the first rear cable tray 31 and less than the first rear cable tray 31 in length, comprises board's pin-jointed ends 321 at one side as well as tray's pin-jointed ends 322 at the other end wherein the board's pin-jointed ends 321 are pivoted on the pin-jointed part 233 of the shifting pin-jointed member 23 (central shifting board 21) by rivet pins 323, allowing the second rear cable tray 32 to be driven by the central shifting board 21 simultaneously. The second rear cable tray 32 is pivoted on the first rear cable tray 31 by means of the tray's pin-jointed ends 322. In a preferred embodiment, both the second rear cable tray 32 and the first rear cable tray 31 complete a flexible connection by means of a movable part 33 which has two pin-jointed ends 331, 332 pivoted on the tray's pin-jointed ends 322, 312 by rivet pins 333, 313.

The case cable organizer in the present disclosure features components manufactured easily and economically because the first front cable tray 11 and the first rear cable tray 31 (the second front cable tray 12, the second rear cable tray 32 and the movable parts 13, 33) can be designed as common parts.

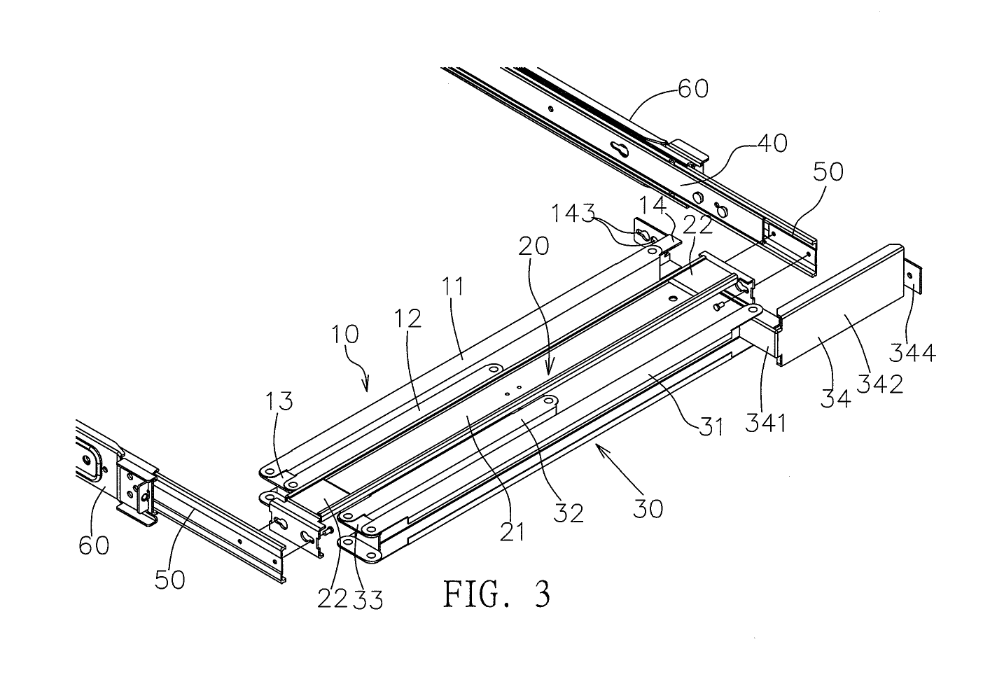

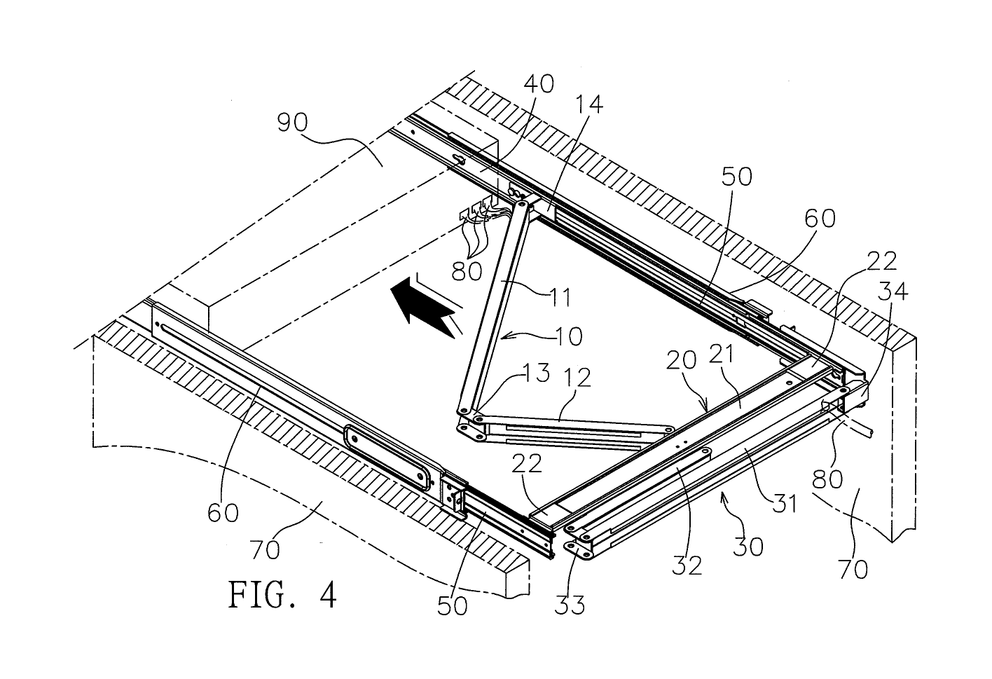

Please refer to FIGS. 3 and 4 which illustrate applications of an assembled case cable organizer structure. As shown in FIGS. 3 and 4, a cabinet 70 is securely provided with an external tack 60, a central track 50 held in the external tack 60, and an internal track 40 held in the central track 50; a case 90 of one computer/electric device connected to the internal track 40 is movably shifted inside the cabinet 70 back and forth. In the structure, the central shifting board 21 is synchronously shifted with the central track 50 when the cabinet pin joint 34 and the fixing pieces 22 are securely fixed on the cabinet 70 and the central track 50, respectively. Certainly, the central track 50 is synchronously shifted with the central shifting board 21 which can be directly connected to the central track 50 with no fixing pieces 22 mounted at both ends. The inner-track pin joint 14 which is fixed on the internal track 40 through the pilot holes 143 allows the first front cable tray 11 to be synchronously driven by the internal track 40.

As shown in FIG. 4, the internal track 40 is able to pull both the first front cable tray 11 and the second front cable tray 12 onward when the case 90 is dragged forward. As shown in FIG. 5, the internal track 40 drives the central track 50 when the case 90 continues moving. Next, the central shifting board 21 which is driven forward by the second front cable tray 12 or the central track 50 continues actuating both the second rear cable tray 32 and the first rear cable tray 31 onward. As such, the cable 80 in the case 90 is driven to be shifted or positioned back and forth by means of the front cable tray unit 10 and the rear cable tray unit 30 with functions like extension and reception. Likewise, the front cable tray unit 10, the shifting device 20 and the rear cable tray unit 30 can be retracted when the case 90 is pushed into the cabinet 70 backward.

It is worth mentioning that the case cable organizer featuring the central shifting board 21 at the center to drive the front cable tray unit 10 and the rear cable tray unit 30 is shifted steadily, smoothly and properly without loud noise or common failure and has durable service life for less maintenance.

Based on the above structure, the case cable organizer structure is characteristic of simplicity, steady and smooth running, and economic effect as well as operation quality in manufacture and utility.

The case cable organizer are specified in but not limited to the preferred embodiments. Any equivalent change or improvement in the structure without departing from spirit of the case cable organizer should be incorporated in claims herein.

What is claimed is:

1. A case cable organizer structure, comprising:
a front cable tray unit comprising a first front cable tray and a second front cable tray which is pivoted on and stays behind said first front cable tray and has board's pin-jointed ends at one side;
a central shifting board which is arranged behind said second front cable tray and provided with pin-jointed parts securely fixed at central front and rear sides of said central shifting board wherein said pin-jointed part at the front side is pivoted on said board's pin-jointed ends of said second front cable tray;
a rear cable tray unit comprising a first rear cable tray and a second rear cable tray which is pivoted on and stays in the front of said first rear cable tray and has board's pin-jointed ends at one side wherein the board's pin jointed ends are pivoted on a pin-jointed part at said central shifting board's rear end.

2. A case cable organizer structure according to claim 1 wherein both said first front cable tray and said second front cable tray are tubular frames in which wiring spaces are designed and said first front cable tray has track's pin-jointed ends at one side.

3. A case cable organizer structure according to claim 2 wherein said track's pin-jointed ends are pivoted on an inner-track pin joint from which a locator with some pilot holes thereon protrude outward.

4. A case cable organizer structure according to claim 1 wherein said second front cable tray is pivoted on said first front cable tray by a movable part, which has pin-jointed ends at two sides pivoted on said first front cable tray and said second front cable tray, respectively.

5. A case cable organizer structure according to claim 3 wherein said central shifting board has a guiding groove with two fixing pieces embedded at both ends and the fixing piece comprises a straight-down solid joint piece on which fixing holes are drilled.

6. A case cable organizer structure according to claim 1 wherein both said first rear cable tray and said second rear cable tray are tubular frames in which wiring spaces are designed and the first rear cable tray has device's pin-jointed ends at one side.

7. A case cable organizer structure according to claim 6 wherein said device's pin-jointed ends are pivoted on a cabinet pin joint comprising a pin jointed plate and a fixed plate, both of which are perpendicularly connected to each other.

8. A case cable organizer structure according to claim 1 wherein said second rear cable tray is pivoted on said first rear cable tray by a movable part, which has pin-jointed ends at both ends pivoted on said first rear cable tray and the second rear cable tray, respectively.

9. A case cable organizer structure according to claim 6 wherein said cabinet pin joint is securely fixed on a cabinet on which an external track, a central tack movably held in said external track, and an internal track movably held in said central tack and a case of a computer/electronic device installed in said cabinet is connected to the internal track.

10. A case cable organizer structure according to claim 5 wherein said fixing piece and said inner-track pin joint are securely fixed on said central track and said internal tack, respectively.

11. A case cable organizer structure according to claim 1 wherein said central shifting board is centrally provided with a shifting pin-jointed member to develop said front pin-jointed part and said rear pin-jointed part.

12. A case cable organizer structure according to claim 11 wherein both said central shifting board and shifting pin-jointed member are integrally formed.

13. A case cable organizer structure according to claim 1 wherein said second front cable tray is less than said first front cable tray in length.

14. A case cable organizer structure according to claim 1 wherein said second rear cable tray is less than said first rear cable tray in length.
